(19) United States
(12) Patent Application Publication
(10) Pub. No.: US 2026/0131564 A1
(43) Pub. Date: May 14, 2026

(54) METHOD OF FORMING ARTICLES COMPRISING TEMPORARY BONDING OF SUBSTRATES

(71) Applicant: CORNING INCORPORATED, CORNING, NY (US)

(72) Inventor: Ya-Huei Chang, Hsinchu County (TW)

(21) Appl. No.: 19/381,352

(22) Filed: Nov. 6, 2025

Related U.S. Application Data
(60) Provisional application No. 63/720,293, filed on Nov. 14, 2024.

(51) Int. Cl. B32B 38/00; B32B 17/10; B32B 18/00; B32B 25/04; B32B 37/12

(52) U.S. Cl. CPC B32B 38/0036; B32B 17/10; B32B 18/00; B32B 25/04; B32B 2037/1253; B32B 2250/03; B32B 2250/40; B32B 2260/046; B32B 2270/00; B32B 2305/72; B32B 2309/02; B32B 2309/04; B32B 2309/105; B32B 2315/02; B32B 2315/08

(57) ABSTRACT

A method of forming an article includes disposing a unitary bonding layer on a first substrate, disposing a second substrate on the unitary bonding layer, and treating the unitary bonding layer with heat at a treatment temperature greater than 80° C. and less than or equal to 400° C. for a treatment period greater than 1 minute and less than or equal to 120 minutes to bond the second substrate to the first substrate, thereby providing a bonding energy of the second substrate to the first substrate greater than or equal to 500 mJ/m². The unitary bonding layer includes an average thickness less than or equal to 10 μm.

This application claims the benefit of priority under 35 U.S.C. § 119 of U.S. Provisional Application Ser. No. 63/720,293 filed on Nov. 14, 2024, the content of which is relied upon and incorporated herein by reference in its entirety.

### FIELD

The present specification generally relates to methods of forming articles comprising temporary bonding of substrates and, in particular, to methods of forming articles having a thin unitary bonding layer with sufficient bonding energy.

### TECHNICAL BACKGROUND

Techniques for processing substrates to meet dimensional or performance characteristics are important to modern industry. Processing techniques include chemical or physical treatments and require precise control of the positioning and motion of the substrate. As the pitch and thickness of device on the substrate become smaller, processing may become more difficult, especially when tight tolerances are desired.

Conventional bonders may not be equipped to activate a thin temporary bonding layer to bond a working substrate to a carrier substrate. As such, articles may need to be transferred to another machine to facilitate bonding, thereby introducing particles and reducing throughput.

Therefore, a continuing need exists for methods of bonding a working substrate to a carrier substrate including improved bonding techniques using thin bonding layers to achieve sufficient bonding strength.

### SUMMARY

According to a first aspect A1, a method of forming an article comprises: disposing a unitary bonding layer on a first substrate, the unitary bonding layer comprising an average thickness less than or equal to 10 μm; disposing a second substrate on the unitary bonding layer; and treating the unitary bonding layer with heat at a treatment temperature greater than 80° C. and less than or equal to 400° C. for a treatment period greater than 1 minute and less than or equal to 120 minutes to bond the second substrate to the first substrate, thereby providing a bonding energy of the second substrate to the first substrate greater than or equal to 500 mJ/m².

A second aspect A2 includes the method of the first aspect A1, wherein the treating the unitary bonding layer with heat is conducted without plasma treatment.

A third aspect A3 includes the method of the first aspect A1 or the second aspect A2, wherein the unitary bonding layer comprises melamine, silane, polyamic acid, polyamide, or combinations thereof.

A fourth aspect A4 includes the method of the first aspect A1 or the second aspect A2, wherein the unitary bonding layer comprises a material comprising a carbonyl group, a cyano group, a trifluoromethyl group, an ester group, a siloxane group, a nitroso group, an isocyanate group, or combinations thereof.

A fifth aspect A5 includes the method of any one of the first through fourth aspects A1-A4, wherein the average thickness of the unitary bonding layer is greater than or equal to 0.1 nm and less than or equal to 1 μm.

A sixth aspect A6 includes the method of any one of the first through fifth aspects A1-A5, wherein the unitary bonding layer comprises a total thickness variation (TTV) less than or equal to 100 nm.

A seventh aspect A7 includes the method of any one of the first through sixth aspects A1-A6, wherein the unitary bonding layer comprises an extinction coefficient greater than or equal to 0.03 at a wavelength from 190 nm to 700 nm.

An eighth aspect A8 includes the method of any one of the first through seventh aspects A1-A7, wherein the treatment temperature is greater than or equal to 100° C. and less than or equal to 350° C.

A ninth aspect A9 includes the method of any one of the first through eighth aspects A1-A8, wherein the treatment period is greater than or equal to 10 minutes and less than or equal to 60 minutes.

A tenth aspect A10 includes the method of any one of the first through ninth aspects A1-A9, wherein the first substrate comprises glass or glass ceramic.

An eleventh aspect A11 includes the method of any one of the first through tenth aspects A1-A10, wherein the first substrate comprises an average thickness greater than or equal to 0.4 mm and less than or equal to 3 mm.

A twelfth aspect A12 includes the method of any one of the first through eleventh aspects A1-A11, wherein the first substrate comprises a total thickness variation (TTV) greater than or equal to 0.1 μm and less than or equal to 5 μm.

A thirteenth aspect A13 includes the method of any one of the first through twelfth aspects A1-A12, wherein the first substrate comprises a surface roughness Ra less than or equal to 30 nm.

A fourteenth aspect A14 includes the method of any one of the first through thirteenth aspects A1-A13, wherein the second substrate comprises glass, an oxide, a nitride, a semiconductor material, a piezoelectric material, or combinations thereof.

A fifteenth aspect A15 includes the method of any one of the first through fourteenth aspects A1-A14, wherein the second substrate comprises an average thickness less than or equal to 800 μm.

A sixteenth aspect A16 includes the method of any one of the first through fifteenth aspects A1-A15, wherein the second substrate comprises a surface roughness Ra less than or equal to 2 nm.

A seventeenth aspect A17 includes the method of any one of the first through sixteenth aspects A1-A16, wherein the method further comprises processing the second substrate, the processed second substrate having an average thickness less than or equal to 10 μm.

An eighteenth aspect A18 includes the method of the seventeenth aspect A17, wherein the processed second substrate comprises a total thickness variation (TTV) less than or equal to 3 μm.

A nineteenth aspect A19 includes the method of the seventeenth aspect A17 or the eighteenth aspect A18, further comprising debonding the processed second substrate from the first substrate.

A twentieth aspect A20 includes the method of any one of the first through nineteenth aspects A1-A19, further comprising curing the unitary bonding layer prior to the disposing the second substrate on the unitary bonding layer.

Additional features and advantages of the methods of forming articles comprising temporary bonding of substrates described herein will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1 is schematic view of a substrate or layer exhibiting thickness deviations and illustrating measurement of total thickness variation (TTV);

FIG. 2 is a flow chart of a method of forming and article, according to one or more embodiments described herein;

FIG. 3 is a schematic view of a unitary bonding layer disposed on a first substrate, according to one or more embodiments described herein;

FIG. 4 is a schematic view of a second substrate disposed on the unitary bonding layer of FIG. 3;

FIG. 5 is a schematic view of a processed second substrate disposed on the unitary bonding layer of FIG. 3;

FIG. 6 is a schematic view of a third substrate disposed on the processed second substrate of FIG. 5; and

FIG. 7 is a schematic view of the processed second substrate of FIG. 5 separated from the first substrate.

### DETAILED DESCRIPTION

Reference will now be made in detail to various embodiments of methods of forming articles having a thin unitary bonding layer with sufficient bonding energy.

According to embodiments, a method of forming an article includes disposing a unitary bonding layer on a first substrate, disposing a second substrate on the unitary bonding layer, and treating the unitary bonding layer with heat at a treatment temperature greater than 80° C. and less than or equal to 400° C. for a treatment period greater than 1 minute and less than or equal to 120 minutes to bond the second substrate to the first substrate, thereby providing a bonding energy of the second substrate to the first substrate greater than or equal to 500 mJ/m². The unitary bonding layer includes an average thickness less than or equal to 10 μm.

Various embodiments of methods of forming articles will be described herein with specific reference to the appended drawings.

Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Directional terms as used herein—for example up, down, right, left, front, back, top, bottom—are made only with reference to the figures as drawn and are not intended to imply absolute orientation.

Unless otherwise expressly stated, it is in no way intended that any method set forth herein be construed as requiring that its steps be performed in a specific order, nor that with any apparatus specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an” and “the” include plural referents unless the context clearly dictates otherwise. Thus, for example, reference to “a” component includes aspects having two or more such components, unless the context clearly indicates otherwise.

As used herein, “bonding strength” and “bonding energy” may be used interchangeably and refer to a measurement of the energy required to separate a first substrate from a second substrate. Bonding energy is determined by using the wedge test method discussed in Tong, Q. Y., et al. “Semiconductor Wafer Bonding,” Annual Reviews of Materials Science, vol. 28, no. 1. pp. 215-241, 1998, which is incorporate herein by reference in its entirety. To summarize the method the bonding energy is determined by inserting a blade between the first substrate and the second substrate to a depth of 10 mm and measuring the crack length. The blade has a thickness of 97 μm to 107 μm. The bonding energy W is related to the Young's modulus E₁ of the first substrate, the thickness t_{w1} of the first substrate, the Young's modulus E₂ of the second substrate, the thickness t_{w2} of the second substrate, a thickness t_{b} of the blade, and a crack length L, as shown in the equation below:

$$W = \frac{3}{8} \frac{{t}_{b}^{2} {E}_{1} {t}_{w 1}^{3} {E}_{2} {t}_{w 2}^{3}}{{L}^{4} ( {E}_{1} {t}_{w 1}^{3} + {E}_{2} {t}_{w 2}^{3} )}$$

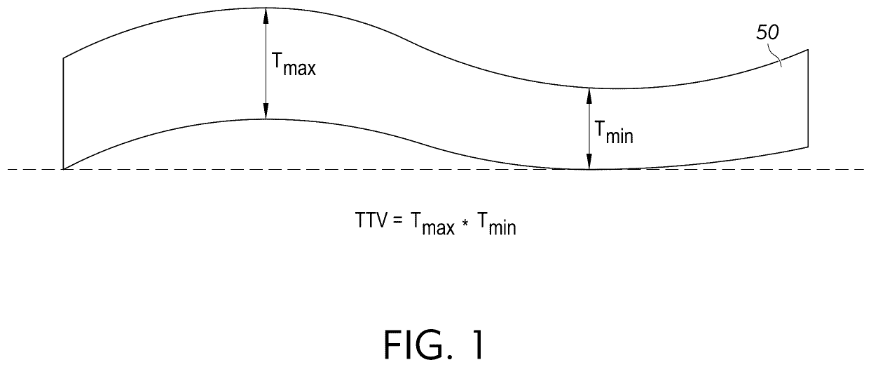

As used herein, “total thickness variation (TTV)” refers to the difference between maximum thickness and the minimum thickness of a substrate or layer over the entire area of the substrate or layer. When determining total thickness variation (TTV), the substrate or layer is held in an unclamped (i.e., free) state. Referring now to FIG. 1 a substrate or layer 50 exhibits thickness deviations and illustrates the total thickness variation (TTV) measurement. As shown in FIG. 1, total thickness variation (TTV) in the substrate or layer 50 is the difference between the maximum thickness Tₘₐₓ and the minimum thickness Tₘᵢₙ of the unclamped substrate or layer 50 over the area of the substrate or layer 50. It is noted that the total thickness variation (TTV) of a substrate or layer is distinguished from the bow or the warp (i.e., flatness) of the substrate or layer. Total thickness variation (TTV) of first, second, and third substrates, as described in the present disclosure, is determined by frequency stepping interferometry using a Tropel® FlatMaster® MSP-300 Glass Wafer Analysis System (available from Corning Incorporated). Total thickness variation (TTV) of the unitary bonding layer is determined by scanning electron microscopy.

As used herein, “surface roughness Rₐ” is measured by atomic force microscopy (AFM). Measurements are made at center, edge, and midway (hallway between center and edge) positions of the first substrate, the second substrate, and the unitary bonding layer. For purposes of surface roughness measurements, edge position refers to a position 2 mm away from the outside boundary of the surface being measured. Ther area of measurement was 2×2 μm² for second substrates and 5×5 μm² or 20×20 μm² for first substrates and unitary bonding layers.

As described herein, requirements for performance and characteristics of processing working substrates are becoming increasingly demanding. In addition to small thickness, for example, it may be desirable for the thickness of the processed working substrate to be highly uniform across the processed working substrate. Uniformity of thickness may be characterized as the total thickness variation (TTV) of the working substrate, where a low total thickness variation (TTV) corresponds to high uniformity of thickness.

In one processing technique, the working substrate may be temporarily bonded to a carrier substrate, processed on the carrier substrate to a state of low total thickness variation (TTV), transferred and bonded to a support substrate, and separated from the carrier substrate to provide a final product in which the processed working substrate is bonded to the support substrate. The working substrate is attached to the carrier substrate with a thin temporary bonding layer that provides sufficient bonding strength to secure the working substrate to the carrier substrate during processing. However, conventional bonders may not be equipped to activate the thin temporary bonding layer to bond the working substrate to the carrier substrate. As such, the articles may need to be transferred to another machine to facilitate bonding, thereby introducing particles and reducing throughput.

Disclosed herein are methods of forming articles which mitigate the aforementioned problems. Specifically, the methods of forming an article described herein comprise treating the unitary bonding layer with a thermal treatment (e.g., a treatment temperature greater than 80° C. and less than or equal to 400° C. for a treatment period greater than 1 minute and less than or equal to 120 minutes) to bond a first substrate to a second substrate. This thermal treatment allows for formation of an article having a thin unitary bonding layer (e.g., average thickness of less than or equal to 10 μm) with sufficient bonding energy (e.g., greater than or equal to 500 mJ/m²) utilizing conventional bonders.

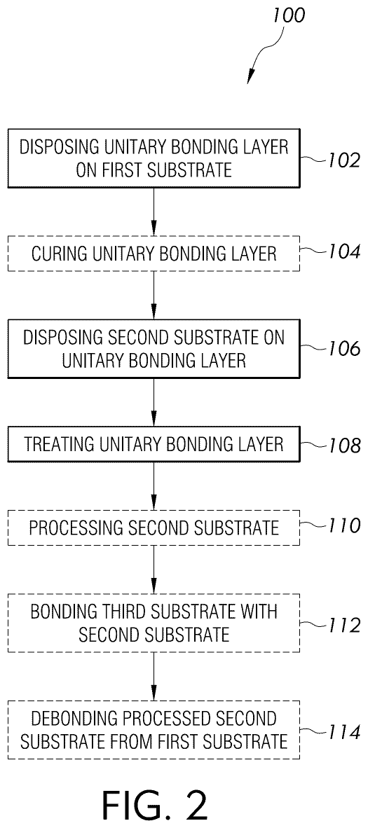

Referring now to FIG. 2, a method of forming an article is shown at 100. Generally, the method 100 includes temporarily bonding a second substrate (e.g., working substrate) to a first substrate (e.g., carrier substrate). The second substrate is processed to provide an article and second substrate with low total thickness variation (TTV). The first substrate may be configured to have low total thickness variation (TTV) in an effort to avoid pre-treatment processes. The first substrate may be utilized for processing the second substrate to reduce the second substrate's total thickness variation (TTV) and may be a transitional support in the sense that it may not be a desired product element. Once the second substrate is processed to a desired total thickness variation (TTV), a third substrate (e.g., a support substrate) may be bonded to the processed surface of the second substrate, the temporary bonding of the second substrate to the first substrate may be reversed, and the second substrate may be separated from the first substrate to provide a product in which the second substrate with low total thickness variation (TTV) is bonded to the third substrate. With this process, the third substrate may not have a low total thickness variation (TTV). The third substrate may have a total thickness variation (TTV) that is greater than the total thickness variation of the second substrate. As a result, products formed by bonding a second substrate with low total thickness variation (TTV) to a third substrate that may not be configured to have a low total thickness variation (TTV) may be formed without subjecting the third substrate to pre-treatment procedures.

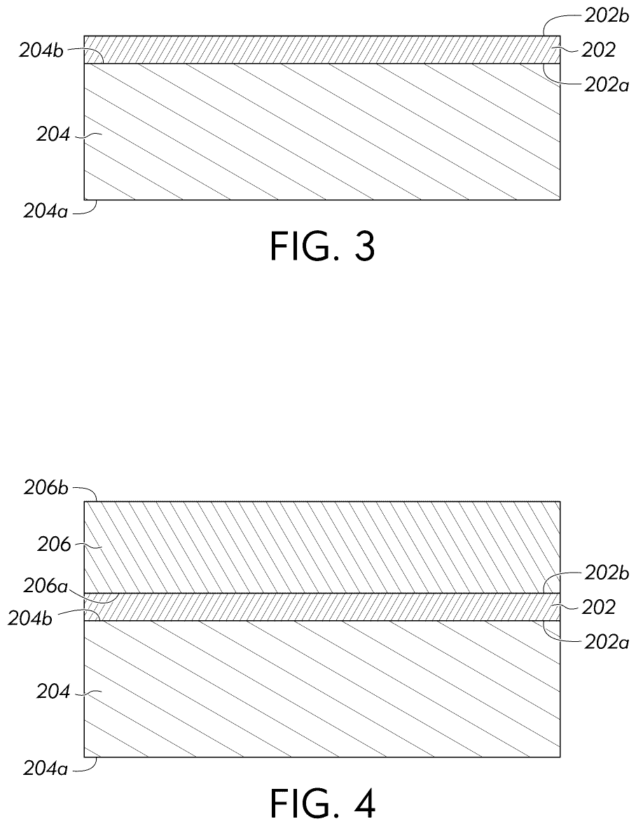

The method 100 begins at block 102 with disposing a unitary bonding layer 202 on a first substrate 204 as shown in FIG. 3. While the method 100 is described herein with respect to disposing the unitary bonding layer 202 on a first substrate 204, in other embodiments, the method 100 may begin with disposing the unitary bonding layer 202 on a second substrate and then disposing the first substrate 204 on the unitary bonding layer 202. The unitary bonding layer 202 comprises a first surface 202a and a second surface 202b opposite the first surface 202a. The first substrate 204 comprises a first surface 204a and a second surface 204b opposite the first surface 204a. The unitary bonding layer 202 may be disposed on the second surface 204b of the first substrate 204.

As used herein, the term “unitary,” when used to describe the bonding layer, means a single or uniform material. That is, while the unitary bonding layer 202 may comprise sub-layers, each sub-layer is made of the same material such that the combination of sub-layers form a uniform material. As described herein, the unitary bonding layer 202 may function as both an adhesive layer to bond the first substrate 204 and a second substrate and a release layer to debond the second substrate from the first substrate 204.

The unitary bonding layer 202 may comprise an average thickness less than or equal to 10 μm to ensure that the second substrate has a low total thickness variation (TTV). While not wishing to be bound by theory, it is believed that a relatively small average thickness of the unitary bonding layer 202 may lead to a low total thickness variation (TTV) for the unitary bonding layer 202. Total thickness variation (TTV) of the unitary bonding layer 202 increases with thickness. A high total thickness variation (TTV) of the unitary bonding layer 202 may lead to an increase in the total thickness variation of the second substrate after processing, even when the total thickness variation (TTV) of the first substrate 204 is low. As such, it may be desirable for the unitary bonding layer 202 to have a low average thickness (e.g., less than or equal to 10 μm). In embodiments, the average thickness of the unitary bonding layer 202 may be greater than or equal to 0.1 nm and less than or equal to 10 μm. In embodiments, the unitary bonding layer 202 may comprise an average thickness greater than or equal to 0.1 nm, greater than or equal to 1 nm, greater than or equal to 10 nm, greater than or equal to 50 nm, or even greater than or equal to 100 nm. In embodiments, the unitary bonding layer 202 may comprise an average thickness less than or equal to 10 μm, less than or equal to 5 μm, less than or equal to 1 μm, or even less than or equal to 500 nm. In embodiments, the unitary bonding layer 202 may comprise an average thickness greater than or equal to 0.1 nm and less than or equal to 10 μm, greater than or equal to 0.1 nm and less than or equal to 5 μm, greater than or equal to 0.1 nm and less than or equal to 1 μm, greater than or equal to 0.1 nm and less than or equal to 500 nm, greater than or equal to 1 nm and less than or equal to 10 μm, greater than or equal to 1 nm and less than or equal to 5 μm, greater than or equal to 1 nm and less than or equal to 1 μm, greater than or equal to 1 nm and less than or equal to 500 nm, greater than or equal to 10 nm and less than or equal to 10 μm, greater than or equal to 10 nm and less than or equal to 5 μm, greater than or equal to 10 nm and less than or equal to 1 μm, greater than or equal to 10 nm and less than or equal to 500 nm, greater than or equal to 50 nm and less than or equal to 10 μm, greater than or equal to 50 nm and less than or equal to 5 μm, greater than or equal to 50 nm and less than or equal to 1 μm, greater than or equal to 50 nm and less than or equal to 500 nm, greater than or equal to 100 nm and less than or equal to 10 μm, greater than or equal to 100 nm and less than or equal to 5 μm, greater than or equal to 100 nm and less than or equal to 1 μm, or even greater than or equal to 100 nm and less than or equal to 500 nm, or any and all sub-ranges formed from any of these endpoints.

The unitary bonding layer 202 may comprise a total thickness variation (TTV) less than or equal to 100 nm to ensure that the second substrate has a low total thickness variation (TTV). As described herein, a high total thickness variation (TTV) of the unitary bonding layer 202 may lead to an increase in the total thickness variation of the second substrate after processing, even when the total thickness variation (TTV) of the first substrate 204 is low. As such, it may be desirable for the unitary bonding layer 202 to have a low total thickness variation (TTV) (e.g., less than or equal to 100 nm). In embodiments, the unitary bonding layer 202 may comprise a total thickness variation (TTV) less than or equal to 100 nm, less than or equal to 50 nm, less than or equal to 25 nm, or even less than or equal to 10 nm. In embodiments, the unitary bonding layer 202 may comprise a total thickness variation (TTV) greater than or equal to 0.1 nm, greater than or equal to 1 nm, greater than or equal to 10 nm, greater than or equal to 25 nm, or even greater than or equal to 50 nm. In embodiments, the unitary bonding layer 202 may comprise a total thickness variation (TTV) greater than or equal to 0.1 nm and less than or equal to 100 nm, greater than or equal to 0.1 nm and less than or equal to 50 nm, greater than or equal to 0.1 nm and less than or equal to 25 nm, greater than or equal to 0.1 nm and less than or equal to 10 nm, greater than or equal to 1 nm and less than or equal to 100 nm, greater than or equal to 1 nm and less than or equal to 50 nm, greater than or equal to 1 nm and less than or equal to 25 nm, greater than or equal to 1 nm and less than or equal to 10 nm, greater than or equal to 10 nm and less than or equal to 100 nm, greater than or equal to 10 nm and less than or equal to 50 nm, greater than or equal to 10 nm and less than or equal to 25 nm, greater than or equal to 25 nm and less than or equal to 100 nm, greater than or equal to 25 nm and less than or equal to 50 nm, or even greater than or equal to 50 nm and less than or equal to 100 nm, or any and all sub-ranges formed from any of these endpoints.

The unitary bonding layer 202, on at least one major surface, comprise a relatively low surface roughness Rₐ (e.g., less than or equal to 2 nm). In embodiments, the unitary bonding layer 202 may comprise a surface roughness Rₐ less than or equal to 2 nm, less than or equal to 1.5 nm, or even less than or equal to 1 nm. In embodiments, the unitary bonding layer 202 may comprise a surface roughness Rₐ greater than or equal to 0.1 nm, greater than or equal to 0.5 nm, or even greater than or equal to 1 nm. In embodiments, the unitary bonding layer 202 may comprise a surface roughness Rₐ greater than or equal to 0.1 nm and less than or equal to 2 nm, greater than or equal to 0.1 nm and less than or equal to 1.5 nm, greater than or equal to 0.1 nm and less than or equal to 1 nm, greater than or equal to 0.5 nm and less than or equal to 2 nm, greater than or equal to 0.5 nm and less than or equal to 1.5 nm, greater than or equal to 0.5 nm and less than or equal to 1 nm, greater than or equal to 1 nm and less than or equal to 2 nm, or even greater than or equal to 1 nm and less than or equal to 1.5 nm, or any and all sub-ranges formed from any of these endpoints.

The unitary bonding layer 202 may comprise a material such that the unitary bonding layer functions as an adhesive layer to bond the first substrate 204 and a second substrate. For example, a bonding mechanism of the unitary bonding layer 202 may be covalent bonding. In embodiments, the unitary bonding layer 202 may comprise melamine, silane, polyamic acid, polyamide, or combinations thereof. In embodiments, the unitary bonding layer 202 may comprise a material comprising a carbonyl group, a cyano group, a trifluoromethyl group, an ester group, a siloxane group, a nitroso group, an isocyanate group, or combinations thereof. In embodiments, the unitary bonding layer 202 may further comprise a solvent, such as propylene glycol methyl ether acetate or cyclopentanone, that may be removed before or during the thermal treatment.

As described herein, the first substrate 204 may be debonded from a second substrate using a light to debond the unitary bonding layer 202. To minimize the energy of light for debonding, the unitary bonding layer 202 may comprise a relatively high extinction coefficient at the wavelength of the light used. As such, in embodiments, the unitary bonding layer 202 may comprise an extinction coefficient greater than or equal to 0.03 at a wavelength from 190 nm to 700 nm. In embodiments, the unitary bonding layer 202 may comprise an extinction coefficient greater than or equal to 0.03, greater than or equal to 0.05, greater than or equal to 0.10, greater than or equal to 0.15, greater than or equal to 0.20, or even greater than or equal to 0.25, at a wavelength from 190 nm to 700 nm. In embodiments, the unitary bonding layer 202 may comprise an extinction coefficient less than or equal to 1.00 or even less than or equal to 0.50, at a wavelength from 190 nm to 700 nm. In embodiments, the unitary bonding layer 202 may comprise an extinction coefficient greater than or equal to 0.03 and less than or equal to 1.00, greater than or equal to 0.03 and less than or equal to 0.50, greater than or equal to 0.05 and less than or equal to 1.00, greater than or equal to 0.05 and less than or equal to 0.50, greater than or equal to 0.10 and less than or equal to 1.00, greater than or equal to 0.10 and less than or equal to 0.15, greater than or equal to 0.15 and less than or equal to 1.00, greater than or equal to 0.15 and less than or equal to 0.50, greater than or equal to 0.20 and less than or equal to 1.00, greater than or equal to 0.20 and less than or equal to 0.50, greater than or equal to 0.25 and less than or equal to 1.00, or even greater than or equal to 0.25 and less than or equal to 0.50, or any and all sub-ranges formed from any of these endpoints, at a wavelength from 190 nm to 700 nm. As used herein, reference to the unitary bonding layer 202 having a particular coefficient “at a wavelength from 190 nm to 700 nm” means that the unitary bonding layer 202 has the particular extinction coefficient at least one wavelength in the specified range of 190 nm to 700 nm.

Example commercial embodiments of the unitary bonding layer 202 may include SPIS-TA401S, a mixture of propylene glycol methyl ether acetate, cyclopentanone, melamine, and silane groups from Shin-Etsu (Tokyo, Japan); and BrewerBOND® 701, a mixture of polyamic acid and polyamide, from Brewer Sciences, Inc. (Rolla, MO).

The first substrate 204 provides a stable platform for the processing of a second substrate. The first substrate 204 may comprise glass or glass ceramic. For example, in embodiments, the first substrate 204 may comprise silicate glass, an aluminosilicate glass, alkali aluminosilicate glass, alkaline earth aluminosilicate glass, borosilicate glass, boro-aluminosilicate glass, alkali aluminoborosilicate glass, alkaline earth aluminoborosilicate glass, soda-lime glass, or fused quartz (fused silica). Example commercial glass substrates include, but are not limited to, HPFS® ArF Grade Fused Silica sold by Corning Incorporated of Corning, New York under glass codes 7980, 7979, and 8655; Corning® carrier glasses sold by Corning Incorporated of Corning, New York under glass codes SG3.4, SG7.8, and SG9.0; and Corning® EAGLE XG® Glass, e.g., boro-aluminosilicate glass also sold by Corning Incorporated of Corning, New York. Other glass substrates include, but are not limited to, Corning Lotus™ NXT Glass, Corning Iris™ Glass, Corning® WILLOW® Glass, Corning® Gorilla® Glass, Corning VALOR® Glass, or PYREX® Glass sold by Corning Incorporated of Corning, New York. In embodiments, the glass or glass ceramic may comprise 50 wt % or more, 60 wt % or more, 70 wt % or more, 80 wt % or more, 90 wt % or more, or 95 wt % or more silica content by weight on an oxide basis. In other embodiments, the first substrate 204 may comprise ceramic or a semiconductor, such as silicon.

The first substrate 204 may have a sufficient thickness so that the first substrate 204 remains rigid without bending or flexing during the processing of a second substrate. Accordingly, in embodiments, the first substrate may comprise an average thickness greater than or equal to 0.4 mm and less than or equal to 3 mm. In embodiments, the first substrate 204 may comprise an average thickness greater than or equal to 0.4 mm, greater than or equal to 0.6 mm, greater than or equal to 0.8 mm, or even greater than or equal to 1 mm. In embodiments, the first substrate 204 may comprise an average thickness less than or equal to 3 mm, less than or equal to 2 mm, or even less than or equal to 1 mm. In embodiments, the first substrate 204 may comprise an average thickness greater than or equal to 0.4 mm and less than or equal to 3 mm, greater than or equal to 0.4 mm and less than or equal to 2 mm, greater than or equal to 0.4 mm and less than or equal to 1 mm, greater than or equal to 0.6 mm and less than or equal to 3 mm, greater than or equal to 0.6 mm and less than or equal to 2 mm, greater than or equal to 0.6 mm and less than or equal to 1 mm, greater than or equal to 0.8 mm and less than or equal to 3 mm, greater than or equal to 0.8 mm and less than or equal to 2 mm, greater than or equal to 0.8 mm and less than or equal to 1 mm, greater than or equal to 1 mm and less than or equal to 3 mm, or even greater than or equal to 1 mm and less than or equal to 2 mm, or any and all sub-ranges formed from any of these endpoints.

The first substrate 204 may have or may be pre-treated to have a low total thickness variation (TTV) before bonding a second substrate with the unitary bonding layer 202. In embodiments, the first substrate 204 may comprise a total thickness variation (TTV) greater than or equal to 0.1 μm and less than or equal to 5 μm. In embodiments, the first substrate 204 may comprise a total thickness variation (TTV) greater than or equal to 0.1 μm, greater than or equal to 0.3 μm, greater than or equal to 0.5 μm, or even greater than or equal to 1 μm. In embodiments, the first substrate 204 may comprise a total thickness variation (TTV) less than or equal to 5 μm, less than or equal to 4 μm, less than or equal to 3 μm, less than or equal to 2 μm, or even less than or equal to 1 μm. In embodiments, the first substrate 204 may comprise a total thickness variation (TTV) greater than or equal to 0.1 μm and less than or equal to 5 μm, greater than or equal to 0.1 μm and less than or equal to 4 μm, greater than or equal to 0.1 μm and less than or equal to 3 μm, greater than or equal to 0.1 μm and less than or equal to 2 μm, greater than or equal to 0.1 μm and less than or equal to 1 μm, greater than or equal to 0.3 μm and less than or equal to 5 μm, greater than or equal to 0.3 μm and less than or equal to 4 μm, greater than or equal to 0.3 μm and less than or equal to 3 μm, greater than or equal to 0.3 μm and less than or equal to 2 μm, greater than or equal to 0.3 μm and less than or equal to 1 μm, greater than or equal to 0.5 μm and less than or equal to 5 μm, greater than or equal to 0.5 μm and less than or equal to 4 μm, greater than or equal to 0.5 μm and less than or equal to 3 μm, greater than or equal to 0.5 μm and less than or equal to 2 μm, greater than or equal to 0.5 μm and less than or equal to 1 μm, greater than or equal to 1 μm and less than or equal to 5 μm, greater than or equal to 1 μm and less than or equal to 4 μm, greater than or equal to 1 μm and less than or equal to 3 μm, or even greater than or equal to 1 μm and less than or equal to 2 μm, or any and all sub-ranges formed from any of these endpoints.

In some embodiments, the second surface 204b of the first substrate 204 may comprise a surface roughness Rₐ less than or equal to 30 nm. While not wishing to be bound by theory, it is believe that in embodiments where the unitary bonding layer 202 is first applied to the first substrate 204, the first substrate 204 may be relatively rougher since the unitary bonding layer 202 will form a surface with relatively low surface roughness (e.g., less than or equal to 2 nm). In embodiments, the second surface 204b of the first substrate 204 may comprise a surface roughness Rₐ less than or equal to 30 nm, less than or equal to 25 nm, less than or equal to 20 nm, or even less than or equal to 15 nm. In embodiments, the second surface 204b of the first substrate 204 may comprise a surface roughness Rₐ greater than or equal to 1 nm, greater than or equal to 5 nm, or even greater than or equal to 10 nm. In embodiments, the second surface 204b of the first substrate 204 may comprise a surface roughness Rₐ greater than or equal to 1 nm and less than or equal to 30 nm, greater than or equal to 1 nm and less than or equal to 25 nm, greater than or equal to 1 nm and less than or equal to 20 nm, greater than or equal to 1 nm and less than or equal to 15 nm, greater than or equal to 5 nm and less than or equal to 30 nm, greater than or equal to 5 nm and less than or equal to 25 nm, greater than or equal to 5 nm and less than or equal to 20 nm, greater than or equal to 5 nm and less than or equal to 15 nm, greater than or equal to 10 nm and less than or equal to 30 nm, greater than or equal to 10 nm and less than or equal to 25 nm, greater than or equal to 10 nm and less than or equal to 20 nm, or even greater than or equal to 10 nm and less than or equal to 15 nm, or any and all sub-ranges formed from any of these endpoints.

In other embodiments, the second surface 204b of the first substrate 204 may comprise a relatively low surface roughness Rₐ (e.g., less than or equal to 2 nm). Without wishing to be bound by theory, it is believed that a relatively low surface roughness of the second surface 204b allows for a reduction in the average thickness of the unitary bonding layer 202, which in turn leads to a reduction in total thickness variation (TTV) of the unitary bonding layer 202. In embodiments, the second surface 204b of the first substrate 204 may comprise a surface roughness Rₐ less than or equal to 2 nm, less than or equal to 1.5 nm, or even less than or equal to 1 nm. In embodiments, the second surface 204b of the first substrate 204 may comprise a surface roughness Rₐ greater than or equal to 0.1 nm, greater than or equal to 0.5 nm, or even greater than or equal to 1 nm. In embodiments, the second surface 204b of the first substrate 204 may comprise a surface roughness Rₐ greater than or equal to 0.1 nm and less than or equal to 2 nm, greater than or equal to 0.1 nm and less than or equal to 1.5 nm, greater than or equal to 0.1 nm and less than or equal to 1 nm, greater than or equal to 0.5 nm and less than or equal to 2 nm, greater than or equal to 0.5 nm and less than or equal to 1.5 nm, greater than or equal to 0.5 nm and less than or equal to 1 nm, greater than or equal to 1 nm and less than or equal to 2 nm, or even greater than or equal to 1 nm and less than or equal to 1.5 nm, or any and all sub-ranges formed from any of these endpoints.

As described in more detail below, in embodiments, the first substrate 204 may comprise a coefficient of thermal expansion (CTE) that matches or is similar to the coefficient of thermal expansion (CTE) of the second substrate.

Referring back to FIG. 2, the method 100 may optionally continue at block 104 with curing the unitary bonding layer 202 prior to disposing a second substrate on the unitary bonding layer 202. In embodiments, the unitary bonding layer 202 may be cured at a temperature greater than or equal to 80° C. and less than or equal to 300° C. for a time period greater than or equal to 10 s and less than or equal to 30 min. Curing may at least partially remove solvent present in the unitary bonding layer 202. After curing, a second substrate may bond to the cured unitary bonding layer 202 when they have similar surface affinity.

Referring again to FIG. 2, the method 100 continues at block 106 with disposing a second substrate 206 on the unitary bonding layer 202 as shown in FIG. 4. The second substrate 206 comprises a first surface 206a and a second surface 206b. The second substrate 206 may be disposed on the second surface 202b of the unitary bonding layer 202. The unitary bonding layer 202 may be disposed between the first substrate 204 and the second substrate 206. The first surface 202a of the unitary bonding layer 202 may directly contact the second surface 204b of the first substrate 204. The second surface 202b of the unitary bonding layer 202 may directly contact the first surface 206a of the second substrate 206.

In embodiments, the second substrate 206 may comprise glass, an oxide, a nitride, a semiconductor, a piezoelectric material, or combinations thereof. For example, in embodiments, the second substrate 206 may comprise glass, glass ceramic, or ceramic, including, for example, sapphire, boron carbide, and/or silicon carbide. In embodiments, the second substrate 206 may comprises an oxide, including, for example, silicon oxides, tantalates, niobates, and/or titanates. In embodiments, the second substrate 206 may comprises a nitride, including, for example, SiNx and/or SiOxNy. In embodiments, the second substrate 206 may comprise a semiconductor material, including, for example, silicon, germanium, gallium arsenide, indium antimonide, indium arsenide, gallium nitride, and/or indium phosphide. In embodiments, the second substrate 206 may comprise a piezoelectric material including, for example, lithium tantalite (LiTaO₃), lithium niobate (LiNbO₃), aluminum nitride (AlN), and/or lead zirconate titanate (PZT) (Pb[ZRₓTi₁₋ₓ]O₃ (0≤x≤1). The second substrate 206 may be comprised of a single layer of material or a plurality of layers (e.g., a laminate) of the same or different materials.

The second substrate 206 may have an average thickness (i.e., before processing) less than or equal to 800 μm. In embodiments, the second substrate 206 may have an initial average thickness less than or equal to 800 μm, less than or equal to 600 μm, less than or equal to 400 μm, or even less than or equal to 200 μm. In embodiments, the second substrate 206 may have an average thickness greater than or equal to 10 μm, greater than or equal to 50 μm, greater than or equal to 100 μm, or even greater than or equal to 200 μm. In embodiments, the second substrate 206 may have an average thickness greater than or equal to 10 μm and less than or equal to 800 μm, greater than or equal to 10 μm and less than or equal to 600 μm, greater than or equal to 10 μm and less than or equal to 400 μm, greater than or equal to 10 μm and less than or equal to 200 μm, greater than or equal to 50 μm and less than or equal to 800 μm, greater than or equal to 50 μm and less than or equal to 600 μm, greater than or equal to 50 μm and less than or equal to 400 μm, greater than or equal to 50 μm and less than or equal to 200 μm, greater than or equal to 100 μm and less than or equal to 800 μm, greater than or equal to 100 μm and less than or equal to 600 μm, greater than or equal to 100 μm and less than or equal to 400 μm, greater than or equal to 100 μm and less than or equal to 200 μm, greater than or equal to 200 μm and less than or equal to 800 μm, greater than or equal to 200 μm and less than or equal to 600 μm, or even greater than or equal to 200 μm and less than or equal to 400 μm, or any and all sub-ranges formed from any of these endpoints.

In some embodiments, the first surface 206a of the second substrate 206 may comprise a relatively low surface roughness Rₐ (e.g., less than or equal to 2 nm). Without wishing to be bound by theory, it is though that a relatively low surface roughness of the first surface 206a allows for a reduction in the average thickness of the unitary bonding layer 202, which in turn leads to a reduction in total thickness variation (TTV) of the unitary bonding layer 202. In embodiments, the first surface 206a of the second substrate 206 may comprise a surface roughness Rₐ less than or equal to 2 nm, less than or equal to 1.5 nm, or even less than or equal to 1 nm. In embodiments, the first surface 206a of the second substrate 206 may comprise a surface roughness Rₐ greater than or equal to 0.1 nm, greater than or equal to 0.5 nm, or even greater than or equal to 1 nm. In embodiments, the first surface 206a of the second substrate 206 may comprise a surface roughness Rₐ greater than or equal to 0.1 nm and less than or equal to 2 nm, greater than or equal to 0.1 nm and less than or equal to 1.5 nm, greater than or equal to 0.1 nm and less than or equal to 1 nm, greater than or equal to 0.5 nm and less than or equal to 2 nm, greater than or equal to 0.5 nm and less than or equal to 1.5 nm, greater than or equal to 0.5 nm and less than or equal to 1 nm, greater than or equal to 1 nm and less than or equal to 2 nm, or even greater than or equal to 1 nm and less than or equal to 1.5 nm, or any and all sub-ranges formed from any of these endpoints.

In other embodiments, the first surface 206a of the second substrate 206 may comprise a surface roughness Rₐ less than or equal to 30 nm. While not wishing to be bound by theory, it is believe that in embodiments where the unitary bonding layer 202 is first applied to the second substrate 206, the second substrate 206 may be relatively rougher since the unitary bonding layer 202 will form a surface with relatively low surface roughness (e.g., less than or equal to 2 nm). In embodiments, the first surface 206a of the second substrate 206 may comprise a surface roughness Rₐ less than or equal to 30 nm, less than or equal to 25 nm, less than or equal to 20 nm, or even less than or equal to 15 nm. In embodiments, the first surface 206a of the second substrate 206 may comprise a surface roughness Rₐ greater than or equal to 1 nm, greater than or equal to 5 nm, or even greater than or equal to 10 nm. In embodiments, the first surface 206a of the second substrate 206 may comprise a surface roughness Rₐ greater than or equal to 1 nm and less than or equal to 30 nm, greater than or equal to 1 nm and less than or equal to 25 nm, greater than or equal to 1 nm and less than or equal to 20 nm, greater than or equal to 1 nm and less than or equal to 15 nm, greater than or equal to 5 nm and less than or equal to 30 nm, greater than or equal to 5 nm and less than or equal to 25 nm, greater than or equal to 5 nm and less than or equal to 20 nm, greater than or equal to 5 nm and less than or equal to 15 nm, greater than or equal to 10 nm and less than or equal to 30 nm, greater than or equal to 10 nm and less than or equal to 25 nm, greater than or equal to 10 nm and less than or equal to 20 nm, or even greater than or equal to 10 nm and less than or equal to 15 nm, or any and all sub-ranges formed from any of these endpoints.

In embodiments, the second substrate 206 may have a coefficient of thermal expansion (CTE) that matches or is similar to the coefficient of thermal expansion (CTE) of the first substrate 204. While not wishing to be bound by theory, a large difference in thermal expansion of the first substrate 204 and the second substrate 206 may be problematic when the attachment of the second substrate 206 to a third substrate includes exposing the second substrate 206 to a range of temperatures (e.g., annealing). A mismatch in coefficient of thermal expansion (CTE) may create thermal stresses that fractures the unitary bonding layer 202 to cause inadvertent separation of the first substrate 204 and the and the second substrate 206. Thermal stresses may also lead to cracking or other damage to the first substrate 204 and the second substrate 206. Additionally or alternatively, the average thicknesses of the first substrate 204 and the second substrate 206 may be configured to reduce thermal stresses associate with CTE mismatch between the first substrate 204 and the second substrate 206 during process of the second substrate 206.

In some embodiments, a difference between the CTE of the first substrate 204 and the CTE of the second substrate 206, at a temperature of 250° C., may be greater than or equal to 0 ppm/° C. to less than or equal to 1.0 ppm/° C., greater than or equal to 0.1 ppm/° C. and less than or equal to 0.9 ppm/° C., greater than or equal to 0.2 ppm/° C. and less than or equal to 0.8 ppm/° C., or even greater than or equal to 0.3 ppm/° C. and less than or equal to 0.7 ppm/° C., or any and all sub-ranges formed from any of these endpoints. In one embodiment, the first substrate may comprise glass and the second substrate 206 may comprise silicon (e.g., a silicon wafer).

Referring back to FIG. 2, the method 100 continues at block 106 with treating the unitary bonding layer 202 with heat to bond the second substrate 206 with the first substrate 204. As described herein, thermal treatment comprises a treatment temperature greater than 80° C. and less than or equal to 400° C. for a treatment period greater than 1 minute and less than or equal to 120 minutes. This thermal treatment allows for formation of an article having a thin unitary bonding layer (e.g., average thickness of less than or equal to 10 μm) with sufficient bonding energy (e.g., greater than or equal to 500 mJ/m²) utilizing conventional bonders. That is, conventional bonders generally are configured to thermally treat the unitary bonding layer 202 as described herein. In embodiments, the treating the unitary bonding layer 202 with heat is conducted without prior or simultaneous plasma treatment.

In embodiments, the treatment temperature may be greater than 80° C. and less than or equal to 400° C. In embodiments, the treatment temperature may be greater than or equal to 100° C. and less than or equal to 350° C. In embodiments, the treatment temperature may be greater than 80° C., greater than or equal to 100° C., greater than or equal to 120° C., greater than or equal to 140° C., greater than or equal to 160° C., greater than or equal to 180° C., or even greater than or equal to 200° C. In embodiments, the treatment temperature may be less than or equal to 400° C., less than or equal to 350° C., less than or equal to 300° C., less than or equal to 250° C., less than or equal to 200° C., or even less than or equal to 180° C. In embodiments, the treatment temperature may be greater than 80° C. and less than or equal to 400° C., greater than 80° C. and less than or equal to 350° C., greater than 80° C. and less than or equal to 300° C., greater than 80° C. and less than or equal to 250° C., greater than 80° C. and less than or equal to 200° C., greater than 80° C. and less than or equal to 180° C., greater than or equal to 100° C. and less than or equal to 400° C., greater than or equal to 100° C. and less than or equal to 350° C., greater than or equal to 100° C. and less than or equal to 300° C., greater than or equal to 100° C. and less than or equal to 250° C., greater than or equal to 100° C. and less than or equal to 200° C., greater than or equal to 100° C. and less than or equal to 180° C., greater than or equal to 120° C. and less than or equal to 400° C., greater than or equal to 120° C. and less than or equal to 350° C., greater than or equal to 120° C. and less than or equal to 300° C., greater than or equal to 120° C. and less than or equal to 250° C., greater than or equal to 120° C. and less than or equal to 200° C., greater than or equal to 120° C. and less than or equal to 180° C., greater than or equal to 140° C. and less than or equal to 400° C., greater than or equal to 140° C. and less than or equal to 350° C., greater than or equal to 140° C. and less than or equal to 300° C., greater than or equal to 140° C. and less than or equal to 250° C., greater than or equal to 140° C. and less than or equal to 200° C., greater than or equal to 160° C. and less than or equal to 400° C., greater than or equal to 160° C. and less than or equal to 350° C., greater than or equal to 160° C. and less than or equal to 300° C., greater than or equal to 160° C. and less than or equal to 250° C., greater than or equal to 160° C. and less than or equal to 200° C., greater than or equal to 180° C. and less than or equal to 400° C., greater than or equal to 168° C. and less than or equal to 350° C., greater than or equal to 180° C. and less than or equal to 300° C., greater than or equal to 180° C. and less than or equal to 250° C., greater than or equal to 180° C. and less than or equal to 200° C., greater than or equal to 200° C. and less than or equal to 400° C., greater than or equal to 200° C. and less than or equal to 350° C., greater than or equal to 200° C. and less than or equal to 300° C., or even greater than or equal to 200° C. and less than or equal to 250° C., or any and all sub-ranges formed from any of these endpoints.

In embodiments, the treatment period may be greater than 1 minute and less than or equal to 120 minutes. In embodiments, the treatment period may be greater than or equal to 10 minutes and less than or equal to 60 minutes. In embodiments, the treatment period may be greater than 1 minute, greater than or equal to 5 minutes, greater than or equal to 10 minutes, greater than or equal to 15 minutes, greater than or equal to 30 minutes, greater than or equal to 45 minutes, or even greater than or equal to 60 minutes. In embodiments, the treatment period may be less than or equal 120 minutes, less than or equal to 100 minutes, or even less than or equal to 60 minutes. In embodiments, the treatment period may be greater than 1 minute and less than or equal to 120 minutes, greater than 1 minute and less than or equal to 100 minutes, greater than 1 minute and less than or equal to 60 minutes, greater than or equal to 5 minutes and less than or equal to 120 minutes, greater than or equal to 5 minutes and less than or equal to 100 minutes, greater than or equal to 5 minutes and less than or equal to 60 minutes, greater than or equal to 10 minutes and less than or equal to 120 minutes, greater than or equal to 10 minutes and less than or equal to 100 minutes, greater than or equal to 10 minutes and less than or equal to 60 minutes, greater than or equal to 15 minutes and less than or equal to 120 minutes, greater than or equal to 15 minutes and less than or equal to 100 minutes, greater than or equal to 15 minutes and less than or equal to 60 minutes, greater than or equal to 30 minutes and less than or equal to 120 minutes, greater than or equal to 30 minutes and less than or equal to 100 minutes, greater than or equal to 30 minutes and less than or equal to 60 minutes, greater than or equal to 45 minutes and less than or equal to 120 minutes, greater than or equal to 45 minutes and less than or equal to 100 minutes, greater than or equal to 45 minutes and less than or equal to 60 minutes, greater than or equal to 60 minutes and less than or equal to 120 minutes, or even greater than or equal to 60 minutes and less than or equal to 100 minutes, or any and all sub-ranges formed from any of these endpoints.

In embodiments, the thermal treatment may comprise application of pressure during heating. In embodiments, a pressing force may be greater than or equal to 0 N and less than or equal to 100 N, greater than or equal to 100 N and less than or equal to 1000 N, greater than or equal to 1000 N and less than or equal to 25000 N, greater than or equal to 2000 N and less than or equal to 20000 N, or even greater than or equal to 3000 N and less than or equal to 15000 N, or any and all sub-ranges formed from any of these endpoints.

As described herein, treating the unitary bonding layer 202 with the thermal treatment described herein provides sufficient bonding strength (e.g., greater than or equal to 500 mJ/m²) to secure the second substrate 206 to the first substrate 204 during processing. In embodiments, the bonding energy of the second substrate 206 to the first substrate 204 may be greater than or equal to 500 mJ/m², greater than or equal to 750 mJ/m², greater than or equal to 1000 mJ/m², greater than or equal to 1250 mJ/m², or even greater than or equal to 1500 mJ/m². As used in the Examples section herein, the term “statistically significant increase” refers to an increase in bonding energy being the result of the applied thermal treatment and not due to error or random chance. In embodiments, the increase in bonding energy of the second substrate 206 to the first substrate 204 may be greater than or equal to 50 mJ/m², greater than or equal to 100 mJ/m², greater than or equal to 250 mJ/m², greater than or equal to 500 mJ/m², or even greater than or equal to 1000 mJ/m².

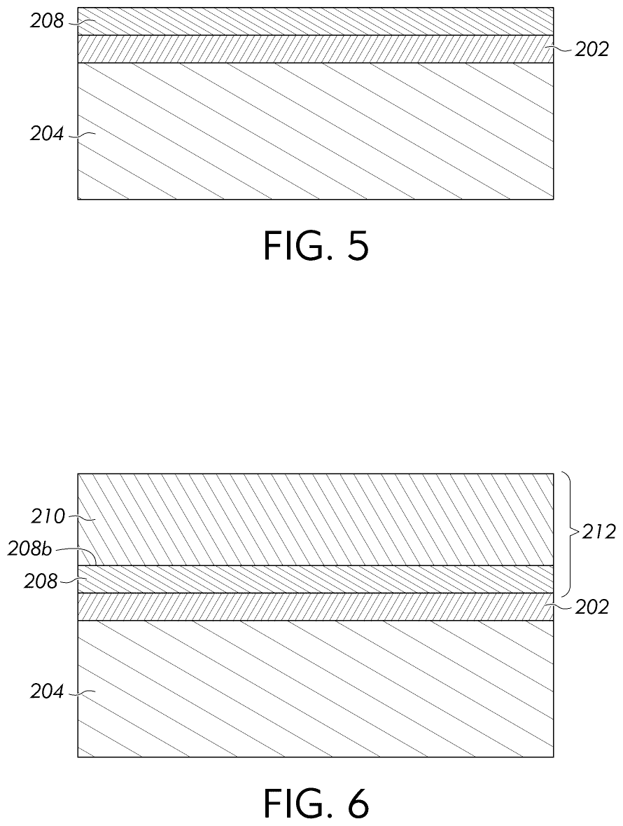

Referring again to FIG. 2, the method 100 may optionally continue at block 110 with processing the second substrate 206 as shown in FIG. 5. In embodiments, the processing the second substrate 206 comprises reducing the thickness or thinning the second substrate 206. Methods of thinning the second substrate 206 may include chemical or mechanical processes or combinations thereof, such as grinding, polishing, abrasion, chemical mechanical planarization (CMP), ion-beam milling, plasma etching, and wet etching.

In embodiments, the processed second substrate 208 may comprise an average thickness less than or equal to 10 μm, less than or equal to 8 μm, less than or equal to 6 μm, less than or equal to 4 μm, or even less than or equal to 2 μm. In embodiments, the processed second substrate 208 may comprise an average thickness greater than or equal to 0.2 μm, greater than or equal to 0.4 μm, greater than or equal to 0.6 μm, greater than or equal to 0.8 μm, or even greater than or equal to 1 μm. In embodiments, the processed second substrate 208 may comprise an average thickness greater than or equal to 0.2 μm and less than or equal to 10 μm, greater than or equal to 0.2 μm and less than or equal to 8 μm, greater than or equal to 0.2 μm and less than or equal to 6 μm, greater than or equal to 0.2 μm and less than or equal to 4 μm, greater than or equal to 0.2 μm and less than or equal to 2 μm, greater than or equal to 0.4 μm and less than or equal to 10 μm, greater than or equal to 0.4 μm and less than or equal to 8 μm, greater than or equal to 0.4 μm and less than or equal to 6 μm, greater than or equal to 0.4 μm and less than or equal to 4 μm, greater than or equal to 0.4 μm and less than or equal to 2 μm, greater than or equal to 0.6 μm and less than or equal to 10 μm, greater than or equal to 0.6 μm and less than or equal to 8 μm, greater than or equal to 0.6 μm and less than or equal to 6 μm, greater than or equal to 0.6 μm and less than or equal to 4 μm, greater than or equal to 0.6 μm and less than or equal to 2 μm, greater than or equal to 0.8 μm and less than or equal to 10 μm, greater than or equal to 0.8 μm and less than or equal to 8 μm, greater than or equal to 0.8 μm and less than or equal to 6 μm, greater than or equal to 0.8 μm and less than or equal to 4 μm, greater than or equal to 0.8 μm and less than or equal to 2 μm, greater than or equal to 1 μm and less than or equal to 10 μm, greater than or equal to 1 μm and less than or equal to 8 μm, greater than or equal to 1 μm and less than or equal to 6 μm, greater than or equal to 1 μm and less than or equal to 4 μm, greater than or equal to 1 μm and less than or equal to 2 μm, or any and all sub-ranges formed from any of these endpoints.

In embodiments, the processed second substrate 208 may comprise a total thickness variation (TTV) less than or equal to 3 μm, less than or equal to 2.5 μm, less than or equal to 2 μm, less than or equal to 1.5 μm, or even less than or equal to 1 μm. In embodiments, the processed second substrate 208 may comprise a total thickness variation (TTV) greater than or equal to 0.1 μm, greater than or equal to 0.3 μm, greater than or equal to 0.5 μm, or even greater than or equal to 0.7 μm. In embodiments, the processed second substrate 208 may comprise a total thickness variation (TTV) greater than or equal to 0.1 μm and less than or equal to 3 μm, greater than or equal to 0.1 μm and less than or equal to 2.5 μm, greater than or equal to 0.1 μm and less than or equal to 2 μm, greater than or equal to 0.1 μm and less than or equal to 1.5 μm, greater than or equal to 0.1 μm and less than or equal to 1 μm, greater than or equal to 0.3 μm and less than or equal to 3 μm, greater than or equal to 0.3 μm and less than or equal to 2.5 μm, greater than or equal to 0.3 μm and less than or equal to 2 μm, greater than or equal to 0.3 μm and less than or equal to 1.5 μm, greater than or equal to 0.3 μm and less than or equal to 1 μm, greater than or equal to 0.5 μm and less than or equal to 3 μm, greater than or equal to 0.5 μm and less than or equal to 2.5 μm, greater than or equal to 0.5 μm and less than or equal to 2 μm, greater than or equal to 0.5 μm and less than or equal to 1.5 μm, greater than or equal to 0.5 μm and less than or equal to 1 μm, greater than or equal to 0.7 μm and less than or equal to 3 μm, greater than or equal to 0.7 μm and less than or equal to 2.5 μm, greater than or equal to 0.7 μm and less than or equal to 2 μm, greater than or equal to 0.7 μm and less than or equal to 1.5 μm, or even greater than or equal to 0.7 μm and less than or equal to 1 μm, or any and all sub-ranges formed from any of these endpoints.

Referring back to FIG. 2, the method 100 may optionally continue at block 112 with bonding a third substrate 210 to a second surface 208b of the processed second substrate 208 as shown in FIG. 6. The bond between the third substrate 210 and the processed second substrate 208 may be a permanent bond and may be formed by fusion bonding. An example bonding mechanism is covalent bonding that may be formed with bonding materials known in the art. Example bonding materials include, but are not limited to, BrewerBOND® 305 from Brewer Sciences, Inc. (Rolla, MO) and bonding materials such as those described in U.S. Pat. No. 9,827,740 and U.S. Appl. Pub. Nos. 2021/0261836 and 2022/0140227, which are incorporated herein by reference in their entireties.

The third substrate 210 may be configured to support electrodes, electrical circuits, waveguides, or other optical, optoelectronic, electronic, and power devices. The third substrate 210 may comprise glass, glass ceramic, or ceramic, including, for example, sapphire, silicon carbide, and/or semiconductor materials such as silicon, germanium, gallium arsenide, indium antimonite, indium arsenide, gallium nitride, and/or indium phosphide. In embodiments, the third substrate 210 may comprise one or more of the materials described herein with respect to the first substrate 204. In embodiments, the third substrate 210 comprises a single layer or a plurality of layers.

The third substrate 210 may comprise a thickness greater than or equal to 100 μm and less than or equal to 1000 μm, greater than or equal to 100 μm and less than or equal to 750 μm, greater than or equal to 100 μm and less than or equal to 500 μm, greater than or equal to 250 μm and less than or equal to 1000 μm, greater than or equal to 250 μm and less than or equal to 750 μm, or even greater than or equal to 250 μm and less than or equal to 500 μm, or any and all sub-ranges formed from any of these endpoints.

The processed second substrate 208 and the third substrate 210 together from a device unit 212. The device unit 212 may constitute an article in which the processed second substrate 208 and the third substrate 210 are configured to provide electrical, optical, optoelectronic, or signal filter functionality.

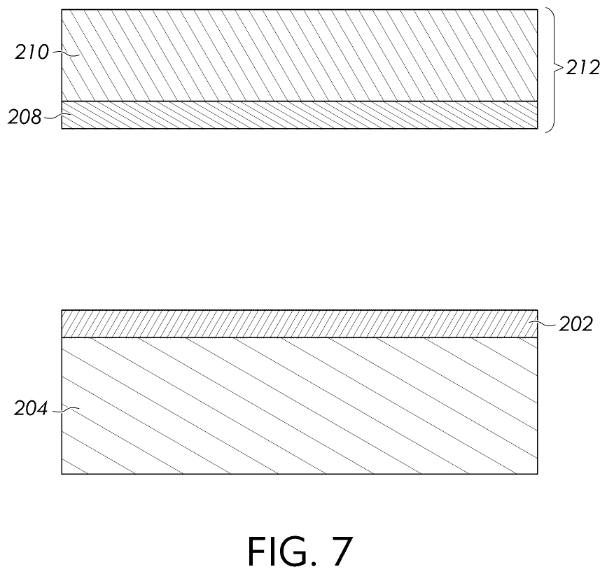

Referring again to FIG. 2, the method 100 may optionally continue at block 114 with debonding the processed second substrate 208 from the first substrate 204 as shown in FIG. 7. Separation of the processed second substrate 208 from the first substrate 204 may be accomplished in a debonding process in which the unitary bonding layer 202 is reversed or weakened to facility or enable release of the processed second substrate 208 from the first substrate 204.

The debonding process may include application of light to reverse or weaken the unitary bonding layer 202. Debonding of the unitary bonding layer 202 may be accomplished with various wavelengths of light, including but not limited to, greater than or equal to 190 nm and less than or equal to 700 nm, greater than or equal to 190 nm and less than or equal to 500 nm, greater than or equal to 190 nm and less than or equal to 450 nm, greater than or equal to 190 nm and less than or equal to 400 nm, greater than or equal to 220 nm and less than or equal to 700 nm, greater than or equal to 220 nm and less than or equal to 500 nm, greater than or equal to 220 nm and less than or equal to 450 nm, greater than or equal to 220 nm and less than or equal to 400 nm, greater than or equal to 240 nm and less than or equal to 700 nm, greater than or equal to 240 nm and less than or equal to 500 nm, greater than or equal to 240 nm and less than or equal to 450 nm, greater than or equal to 240 nm and less than or equal to 400 nm, greater than or equal to 260 nm and less than or equal to 700 nm, greater than or equal to 260 nm and less than or equal to 500 nm, greater than or equal to 260 nm and less than or equal to 450 nm, greater than or equal to 260 nm and less than or equal to 400 nm, greater than or equal to 280 nm and less than or equal to 700 nm, greater than or equal to 280 nm and less than or equal to 500 nm, greater than or equal to 280 nm and less than or equal to 450 nm, greater than or equal to 280 nm and less than or equal to 400 nm, greater than or equal to 300 nm and less than or equal to 700 nm, greater than or equal to 300 nm and less than or equal to 500 nm, greater than or equal to 300 nm and less than or equal to 450 nm, or even greater than or equal to 300 nm and less than or equal to 400 nm, or any and all sub-ranges formed from any of these endpoints.

Residue from the unitary bonding layer 202, if present on the first substrate 204 or the processed second substrate 208 after debonding, may be removed by cleaning. Cleaning processes may include treatment with a solvent, sonic cleaning, air jet, wiping, brushing, or plasma treatment. After debonding, if the first substrate 204 remains in good condition, it may be reused in the processing of other second substrates.

### EXAMPLES

In order that various embodiments be more readily understood, reference is made to the following examples, which are intended to illustrate various embodiments of methods of forming an article as described herein.

### Bonding First Glass Substrate to Second Glass Substrate at Different Treatment Temperatures

To form example article EA1, a first glass substrate was wetted with cyclopentanone, to control the surface wettability, by spin coating at 1000 rpm for 10 seconds. A unitary bonding layer of SPIS-TA401S, a mixture of propylene glycol methyl ether acetate, cyclopentanone, melamine, and silane groups from Shin-Etsu (Tokyo, Japan), was then spin coated on the wetted first glass substrate at a spin speed of 5000 rpm for 120 seconds. The unitary bonding layer thickness was about 220-300 nm. The unitary bonding layer was then pre-baked at 130° C. for 90 seconds and then cured at 250° C. for 10 minutes. After curing, a second glass substrate was contacted with and attached to the cured unitary bonding layer to form example article EA1. Referring now to Table 1, the bonding energy of example article EA1 at 25° C. (i.e., upon initial contact) was 552 mJ/m².

To form example article EA2, a first glass substrate was wetted with cyclopentanone by spin coating at 1000 rpm for 10 seconds. A unitary bonding layer of BrewerBOND® 701, a mixture of polyamic acid and polyamide from Brewer Sciences, Inc. (Rolla, MO), was then spin coated on the wetted first glass substrate at a spin speed of 2500 rpm for 35 seconds and cured at 250° C. for 10 minutes. The unitary bonding layer thickness was about 90-110 nm. After curing, a second glass substrate was contacted with and attached to the cured unitary bonding layer to form example article EA2. Referring now to Table 1, the bonding energy of example article EA2 at 25° C. (i.e., upon initial contact) was 246 mJ/m².

After initial contact, samples of example articles EA1 and EA2 were then subjected to thermal treatment for 60 minutes at the individual treatment temperatures (i.e., each sample was subjected to thermal treatment at a single treatment temperature) listed in Table 1. The samples were then cooled to room temperature and the bonding energies were measured. The corresponding bonding energies at the different treatment temperatures are listed in Table 1 and provided in units of mJ/m².

TABLE 1

| Temperature (° C.) | EA1 | EA2 |
|---|---|---|
| 25 | 552 ± 317 | 246 ± 24 |
| 80 | 844 ± 133 | 199 ± 23 |
| 130 | 1173 ± 228 | 474 ± 174 |
| 175-180 | 3735 ± 187 | 2172 ± 122 |
| 250 | — | 7070 ± 1019 |
| 300 | — | 8798 ± 431 |

As shown in Table 1, example articles EA1 and EA2 demonstrated statistically significant increases in bonding energy after being subjected to thermal treatment at a treatment temperature greater than 80° C., particularly at 130° C. Example articles EA1 and EA2 continued to demonstrated increasing bonding energies as the treatment temperature was increased to 175-180° C. Example article EA2 continued to demonstrate increasing bonding energies as the treatment temperature was increased to 250° C. and 300° C. As indicated by example articles EA1 and EA2, the methods described herein may be used to form articles having a thin unitary bonding layer (e.g., average thickness of less than or equal to 10 μm) with sufficient bonding energy (e.g., greater than or equal to 500 mJ/m²).

### Bonding First Glass Substrate to Second Silicon Substrate at Different Treatment Temperatures

To form example article EA3, a first glass substrate was wetted with cyclopentanone by spin coating at 1000 rpm for 10 seconds. A unitary bonding layer of SPIS-TA401S, a mixture of propylene glycol methyl ether acetate, cyclopentanone, melamine, and silane groups from Shin-Etsu (Tokyo, Japan), was then spin coated on the wetted first glass substrate at a spin speed of 5000 rpm for 120 seconds. The unitary bonding layer thickness was about 220-300 nm. The unitary bonding layer was then pre-baked at 130° C. for 90 seconds and then cured at 250° C. for 10 minutes. After curing, a second silicon substrate was contacted with and attached to the cured unitary bonding layer to form example article EA3. Referring now to Table 2, the bonding energy of example article EA3 at 25° C. (i.e., upon initial contact) was 321 mJ/m². After initial contact, example article EA3 was then subjected to thermal treatment for 60 minutes at the individual treatment temperatures listed in Table 2. The corresponding bonding energies at the different treatment temperatures are listed in Table 2 and provided in units of mJ/m².

TABLE 2

| Temperature (° C.) | EA3 |
|---|---|
| 25 | 321 ± 22 |
| 80 | 195 ± 6.9 |
| 130 | 466 ± 44 |
| 175-180 | 1415 ± 114 |

As shown in Table 2, example article EA3 demonstrated a statistically significant increase in bonding energy after being subjected to thermal treatment at a treatment temperature greater than 80° C., particularly at 130° C. Example Article EA3 continued to demonstrate increasing bonding energy as the as the treatment temperature was increased to 175-180° C. As indicated by example article EA3, the methods described herein may be used to form articles having a thin unitary bonding layer (e.g., average thickness of less than or equal to 10 μm) with sufficient bonding energy (e.g., greater than or equal to 500 mJ/m²).

### Bonding First Glass Substrate to Second Silicon Substrate for Different Treatment Periods

To form example article EA4, a first glass substrate was wetted with cyclopentanone by spin coating at 1000 rpm for 10 seconds. A unitary bonding layer of SPIS-TA401S, a mixture of propylene glycol methyl ether acetate, cyclopentanone, melamine, and silane groups from Shin-Etsu (Tokyo, Japan), was then spin coated on the wetted first glass substrate at a spin speed of 5000 rpm for 120 seconds. The unitary bonding layer thickness was about 220-300 nm. The unitary bonding layer was then pre-baked at 130° C. for 90 seconds and then cured at 250° C. for 10 minutes. After curing, a second silicon substrate was contacted with and attached to the cured unitary bonding layer to form example article EA4. Referring to Table 3, the bonding energy of example article EA4 at 25° C. (i.e., upon initial contact) was 552 mJ/m².

To form example article EA5, a first glass substrate was wetted with cyclopentanone by spin coating at 1000 rpm for 10 seconds. A unitary bonding layer of BrewerBOND® 701, a mixture of polyamic acid and polyamide, from Brewer Sciences, Inc. (Rolla, MO), was then spin coated on the wetted first glass substrate at a spin speed of 2500 rpm for 35 seconds and cured at 250° C. for 10 minutes. The unitary bonding layer thickness was about 90-110 nm. After curing, a second silicon substrate was contacted with and attached to the cured unitary bonding layer to form example article EA5. Referring to Table 3, the bonding energy of example article EA2 at 25° C. (i.e., upon initial contact) was 246 mJ/m².

To form example article EA6, a first glass substrate was wetted with cyclopentanone by spin coating at 1000 rpm for 10 seconds. A unitary bonding layer of BrewerBOND® 701, a mixture of polyamic acid and polyamide, from Brewer Sciences, Inc. (Rolla, MO), was then spin coated on the wetted first glass substrate at a spin speed of 2500 rpm for 35 seconds and cured at 250° C. for 10 minutes. The unitary bonding layer thickness was about 90-110 nm. After curing, a second silicon substrate was contacted with and attached to the cured unitary bonding layer to form example article EA6. Referring to Table 3, the bonding energy of example article EA6 at 25° C. (i.e., upon initial contact) was 246 mJ/m².

After initial contact, example articles EA4, EA5, and EA6 were then subjected to thermal treatment for the different treatment periods at either 180° C. or 250° C. The corresponding bonding energies under different treatment periods are listed in Table 3 and provided in units of mJ/m².

TABLE 3

| Treatment | EA4 | EA5 | EA6 |
|---|---|---|---|
| No treatment | 552 ± 317 | 246 ± 24 | 246 ± 24 |
| Temperature (° C.) | 180 | 180 | 250 |
| 1 minute | 376 ± 26 | 376 ± 26 | 390 ± 43 |
| 10 minutes | 1142 ± 107 | 1114 ± 107 | 2145 ± 408 |
| 30 minutes | 1672 ± 24 | 986 ± 290 | 3661 ± 431 |
| 60 minutes | 1415 ± 114 | 1114 ± 107 | 4858 ± 580 |

As shown in Table 3, example articles EA4-EA6 demonstrated statistically significant increases in bonding energy after being subjected to thermal treatment for a treatment period greater than 1 minute, particularly 10 minutes. While not wishing to be bound by theory, the decrease in bonding energy of example article EA4 after a treatment period of 1 minute may have been because a treatment temperature of 180° C. for a treatment period of 1 minute was not sufficient to form covalent bonds in the unitary bonding layer. While also not wishing to be bound by theory, the unitary bonding layer of example article EA5, when considering the margin of error, may have reached a plateau after being subjected to thermal treatment for 30 minutes. While also not wishing to be bound by theory, the decrease in bonding energy for example article EA4 may have been related to its maximum endurance temperature. The unitary bonding layer of example article EA4 had a maximum endurance temperature of 200° C. After being subjected to thermal treatment at 180 C for 60 minutes, the unitary bonding layer of example article EA4 may have started to degrade, leading to a decrease in bonding energy. As indicated by example article EA4-EA6, the methods described herein may be used to form articles having a thin unitary bonding layer (e.g., average thickness of less than or equal to 10 μm) with sufficient bonding energy (e.g., greater than or equal to 500 mJ/m²).

It will be apparent to those skilled in the art that various modifications and variations may be made to the embodiments described herein without departing from the spirit and scope of the claimed subject matter. Thus, it is intended that the specification cover the modifications and variations of the various embodiments described herein provided such modification and variations come within the scope of the appended claims and their equivalents.

What is claimed is:

1. A method of forming an article comprising:
disposing a unitary bonding layer on a first substrate, the unitary bonding layer comprising an average thickness less than or equal to 10 μm;
disposing a second substrate on the unitary bonding layer; and
treating the unitary bonding layer with heat at a treatment temperature greater than 80° C. and less than or equal to 400° C. for a treatment period greater than 1 minute and less than or equal to 120 minutes to bond the second substrate to the first substrate, thereby providing a bonding energy of the second substrate to the first substrate greater than or equal to 500 mJ/m².

2. The method of claim 1, wherein the treating the unitary bonding layer with heat is conducted without plasma treatment.

3. The method of claim 1, wherein the unitary bonding layer comprises melamine, silane, polyamic acid, polyamide, or combinations thereof.

4. The method of claim 1, wherein the unitary bonding layer comprises a material comprising a carbonyl group, a cyano group, a trifluoromethyl group, an ester group, a siloxane group, a nitroso group, an isocyanate group, or combinations thereof.

5. The method of claim 1, wherein the average thickness of the unitary bonding layer is greater than or equal to 0.1 nm and less than or equal to 1 μm.

6. The method of claim 1, wherein the unitary bonding layer comprises a total thickness variation (TTV) less than or equal to 100 nm.

7. The method of claim 1, wherein the unitary bonding layer comprises an extinction coefficient greater than or equal to 0.03 at a wavelength from 190 nm to 700 nm.

8. The method of claim 1, wherein the treatment temperature is greater than or equal to 100° C. and less than or equal to 350° C.

9. The method of claim 1, wherein the treatment period is greater than or equal to 10 minutes and less than or equal to 60 minutes.

10. The method of claim 1, wherein the first substrate comprises glass or glass ceramic.

11. The method of claim 1, wherein the first substrate comprises an average thickness greater than or equal to 0.4 mm and less than or equal to 3 mm.

12. The method of claim 1, wherein the first substrate comprises a total thickness variation (TTV) greater than or equal to 0.1 μm and less than or equal to 5 μm.

13. The method of claim 1, wherein the first substrate comprises a surface roughness Rₐ less than or equal to 30 nm.

14. The method of claim 1, wherein the second substrate comprises glass, an oxide, a nitride, a semiconductor material, a piezoelectric material, or combinations thereof.

15. The method of claim 1, wherein the second substrate comprises an average thickness less than or equal to 800 μm.

16. The method of claim 1, wherein the second substrate comprises a surface roughness Rₐ less than or equal to 2 nm.

17. The method of claim 1, wherein the method further comprises processing the second substrate, the processed second substrate having an average thickness less than or equal to 10 μm.

18. The method of claim 17, wherein the processed second substrate comprises a total thickness variation (TTV) less than or equal to 3 μm.

19. The method of claim 17, further comprising debonding the processed second substrate from the first substrate.

20. The method of claim 1, further comprising curing the unitary bonding layer prior to the disposing the second substrate on the unitary bonding layer.
